(19) United States
(12) Patent Application Publication
(10) Pub. No.: US 2026/0006899 A1
(43) Pub. Date: Jan. 1, 2026

(54) GALLIUM NITRIDE POWER DEVICE WITH WIDE-RANGE WORKING GATE VOLTAGE

(71) Applicant: SOUTHEAST UNIVERSITY, Nanjing (CN)

(72) Inventors: Weifeng SUN, Nanjing (CN); Siyang LIU, Nanjing (CN); Sheng LI, Nanjing (CN); Ziyu CHEN, Nanjing (CN); Longxing SHI, Nanjing (CN)

(73) Assignee: SOUTHEAST UNIVERSITY, Nanjing (CN)

(21) Appl. No.: 19/132,833

(22) PCT Filed: Jan. 24, 2025
(86) PCT No.: PCT/CN2025/074522

§ 371 Date: May 26, 2025

(30) Foreign Application Priority Data
May 21, 2024 (CN) 202410632114.1

(51) Int. Cl. H10D 84/82; H01L 23/528; H10D 30/47; H10D 62/10; H10D 62/85

(52) U.S. Cl. CPC H10D 84/82; H01L 23/5283; H10D 30/471; H10D 62/102; H10D 62/8503

(57) ABSTRACT

A gallium nitride power device with wide-range working gate voltage structurally includes a base and isolation regions, wherein the base is provided with a substrate, a nucleating layer, a buffer layer, a channel layer, a barrier layer and a passivation layer in sequence from the bottom up, and a voltage-limiting tube region, a power tube region and a bleed-off tube region are arranged on the barrier layer. A first metallic drain electrode in the voltage-limiting tube region and a third metallic gate electrode in the bleed-off tube region are connected via a first metallic interconnector and connected to an input gate voltage, and a first metallic source electrode in the voltage-limiting tube region, a second metallic gate electrode in the power tube region and a third metallic drain electrode in the bleed-off tube region are connected via a second metallic interconnector,

### CROSS REFERENCE TO THE RELATED APPLICATIONS

This application is the national phase entry of International Application No. PCT/CN2025/074522, filed on Jan. 24, 2025, which is based upon and claims priority to Chinese Patent Application No. 202410632114.1, filed on May 21, 2024, the entire contents of which are incorporated herein by reference.

### TECHNICAL FIELD

The present invention belongs to the field of power semiconductor devices, and in particular, relates to a gallium nitride power device with wide-range working gate voltage.

### BACKGROUND

Gallium nitride (GaN), as one of the typical representative wide bandgap semiconductors, has the characteristics of wide bandgap, high breakdown electric field, high electron mobility, high thermal conductivity and the like. In addition, it has smaller on-resistance and faster response speed and thus has been widely used in high-frequency and high-temperature power circuits.

Taking an AlGaN/GaN heterojunction as an example, a two-dimensional electron gas (2DEG) with high mobility and high electron saturation rate can be produced on the surface region of GaN without doping due to the action of spontaneous polarization and piezoelectric polarization within the structure. This is embodied as a depletion-mode device under conventional conditions. Considering the safety and energy issues in the use of the devices, it is more urgent to conduct a study on enhancement mode devices, in which p-GaN technologies have attracted great attention.

Due to the limitations of epitaxial structure and growth process, a conventional gallium nitride device of a Schottky gate structure with a p-GaN cap layer suffers from the problem of small gate voltage swing range. The gate voltage swing of a Si-based MOSFET can reach 20 V, while the gate voltage swing of the gallium nitride device of the Schottky gate structure with the p-GaN cap layer is not more than 8 V, resulting in extremely high complexity required in circuit design and packaging. Moreover, the conventional gallium nitride device of the Schottky gate structure with the p-GaN cap layer is equivalently provided with a pair of back-to-back diodes, and due to the charge storage effect, the device cannot release electrons in the P-type gallium nitride cap layer in time under the condition of repeated switching, resulting in unstable threshold of the device. Furthermore, even with a relatively more stable threshold, a gallium nitride device of an ohmic gate structure with a p-GaN cap layer cannot work stably under the condition of high gate voltage due to its larger gate leakage and smaller gate voltage swing. The above problems of small gate voltage swing and unstable threshold lead to a range of reliability problems of the device in system applications, and seriously affect the practical application and development of the gallium nitride device of the Schottky gate structure with the p-GaN cap layer.

In addition, similarly in a conventional GaN/AlGaN heterojunction, a two-dimensional hold gas (2DEG) can be produced on the lower surface of GaN without doping due to the action of spontaneous polarization and piezoelectric polarization within the structure. However, it cannot be used as a major power device in a high-power circuit due to its low mobility.

### SUMMARY

Technical problems: In view of the problems of small gate voltage swing and unstable threshold of the above conventional enhancement-mode gallium nitride power device, the present invention provides a gallium nitride power device with wide-range working gate voltage, by which the gate voltage swing of the device can be effectively improved and the threshold stability of the device can be enhanced at the same time.

Technical solution: a gallium nitride power device with wide-range working gate voltage includes: a base, the base including a substrate, on which a nucleating layer, a buffer layer, a channel layer, a barrier layer and a passivation layer are arranged in sequence; and isolation regions, wherein a voltage-limiting tube region, a power tube region and a bleed-off tube region are arranged on the barrier layer;
the voltage-limiting tube region includes a first metallic source electrode, a first P-type gallium nitride cap layer and a first metallic drain electrode, which are connected to an upper surface of the barrier layer, and a first metallic gate electrode is arranged on an upper surface of the first P-type gallium nitride cap layer;
the power tube region includes a second metallic source electrode, a second P-type gallium nitride cap layer and a second metallic drain electrode, which are connected to the upper surface of the barrier layer, and a second metallic gate electrode is arranged on an upper surface of the second P-type gallium nitride cap layer;
the bleed-off tube region includes a third metallic source electrode, a third P-type gallium nitride cap layer and a third metallic drain electrode, which are connected to the upper surface of the barrier layer, a PFET gate dielectric layer is arranged on an upper surface of the third P-type gallium nitride cap layer, and a third metallic gate electrode is arranged on an upper surface of the PFET gate dielectric layer.

Preferably, the bleed-off tube region has characteristics of a depletion-mode gallium nitride PFET device as follows: when a voltage of the third metallic gate electrode is less than a positive threshold voltage, the device is turned on; and when the voltage of the third metallic gate electrode is greater than the positive threshold voltage, the device is turned off.

Preferably, the third P-type gallium nitride cap layer bas a thickness of 50 nm to 300 nm.

Preferably, the third P-type gallium nitride cap layer is shaped as a groove.

Preferably, the groove of the third P-type gallium nitride cap layer has a maximum depth of 270 nm.

Preferably, the PFET gate dielectric layer has a thickness of 1 nm to 50 nm.

Preferably, the PFET gate dielectric layer is one or a combination of several of silicon nitride, aluminum nitride, alumina and silicon oxide.

Beneficial effects: Compared with the prior art, the present invention has the following beneficial effects.
(1) Increased gate voltage swing. In the present invention, the saturation characteristics of gallium nitride HEMT are used in such a way that, when the voltage of the first metallic gate electrode in the voltage-limiting tube region is greater than its positive threshold voltage, the increased part of the input gate voltage is applied between the drain electrode and the source electrode in the voltage-limiting tube region to stabilize the voltage of the second metallic gate electrode in the power tube region within its working voltage range, such that the gate voltage swing of the whole device is greatly improved.
(2) Enhanced threshold stability. In the present invention, the switching characteristics of the depletion-mode gallium nitride PFET are used in such a way that, when the voltage of the third metallic gate electrode in the bleed-off tube region is less than its positive threshold, a bleed-off channel is established for charges stored in the second P-type gallium nitride cap layer in the power tube region to effectively eliminate the charge storage effect, such that the threshold stability of the device is significantly enhanced.
(3) High degree of integration and less parasitism. In the present invention, the isolation regions are introduced between the N-channel gallium nitride device and the P-channel gallium nitride device, and the devices are directly connected with each other via metal wires, such that the degree of device integration is increased and the adverse effects caused by parasitism are reduced.

### BRIEF DESCRIPTION OF THE DRAWINGS

FIG. 1 is a schematic structural diagram of a conventional p-GaN power device;

FIG. 2 is a curve graph of transfer characteristics of a device according to the present invention;

FIG. 3 is a curve graph showing a relation between a voltage of a second metallic gate electrode and an input gate voltage of the device according to the present invention;

FIG. 4 is a schematic diagram of a gallium nitride power device with wide-range working gate voltage according to the present invention;

FIG. 5 is an equivalent circuit diagram according to the present invention;

FIG. 6 is a schematic diagram of another gallium nitride power device with wide-range working gate voltage according to Embodiment 2 of the present invention; and

FIG. 7 is an equivalent circuit diagram of another gallium nitride power device with wide-range working gate voltage according to Embodiment 2 of the present invention.

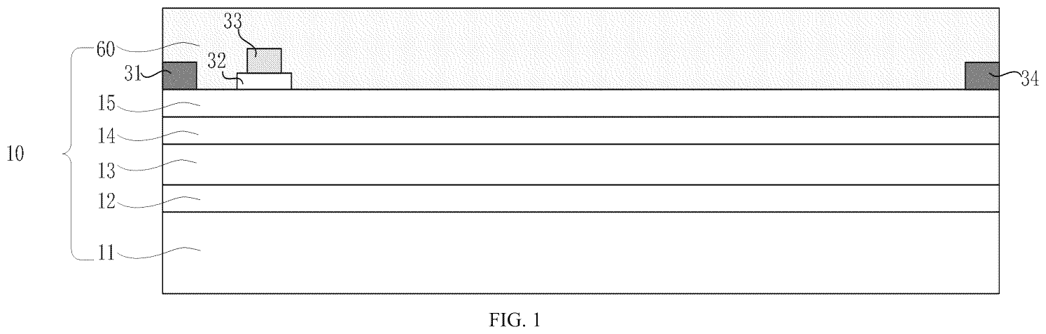

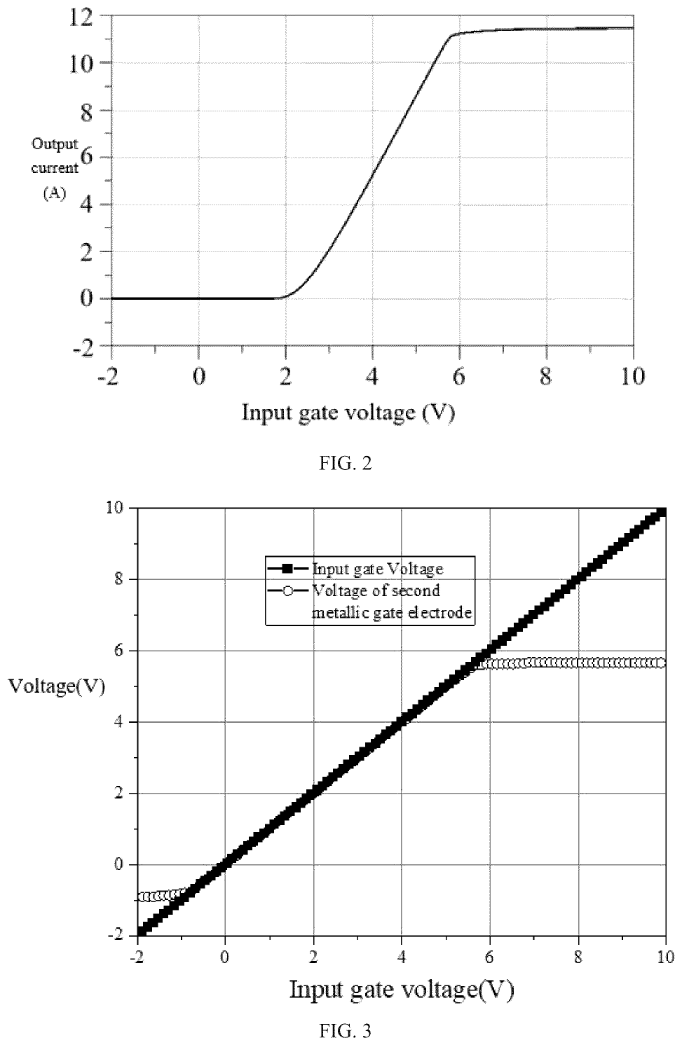

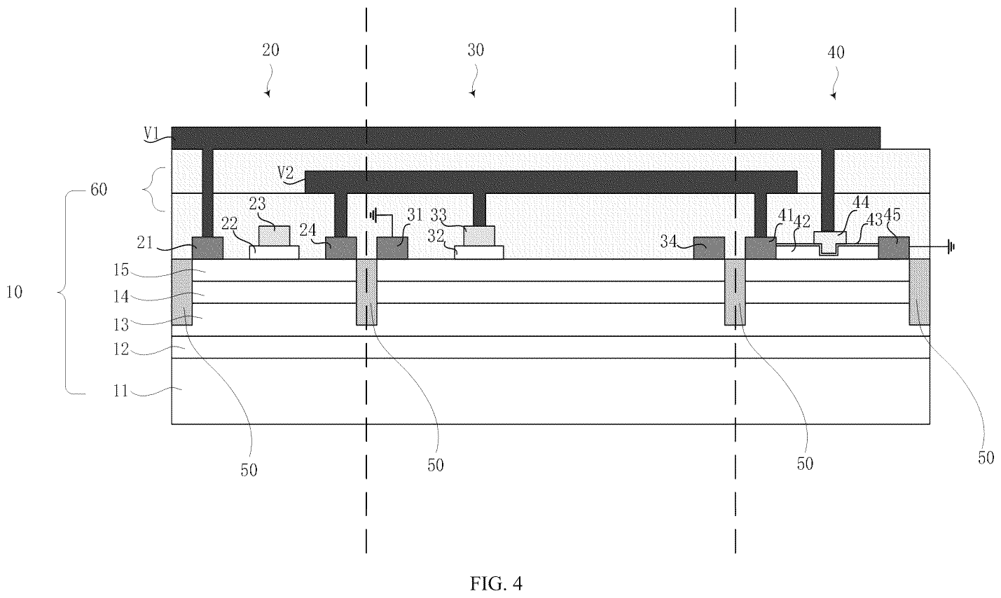

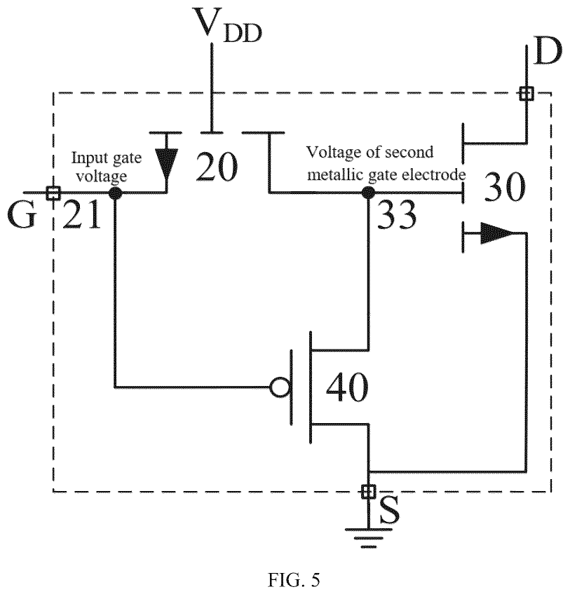

### DETAILED DESCRIPTION OF THE EMBODIMENTS

The present invention will be further described in detail below in conjunction with the accompanying drawings and specific embodiments.

### Embodiment 1

A gallium nitride power device with wide-range working gate voltage structurally includes: a base 10, the base 10 including a substrate 11, on which a nucleating layer 12, a buffer layer 13, a channel layer 14, a barrier layer 15 and a passivation layer 60 are arranged in sequence; and isolation regions 50. A voltage-limiting tube region 20, a power tube region 30 and a bleed-off tube region 40 are arranged on the barrier layer 15.

The voltage-limiting tube region 20 includes a first metallic source electrode 21, a first P-type gallium nitride cap layer 22 and a first metallic drain electrode 24, which are connected to an upper surface of the barrier layer 15, and a first metallic gate electrode 23 is arranged on an upper surface of the first P-type gallium nitride cap layer 22.

The power tube region 30 includes a second metallic source electrode 31, a second P-type gallium nitride cap layer 32 and a second metallic drain electrode 34, which are connected to the upper surface of the barrier layer 15, and a second metallic gate electrode 33 is arranged on an upper surface of the second P-type gallium nitride cap layer 32.

The bleed-off tube region 40 includes a third metallic source electrode 45, a third P-type gallium nitride cap layer 42 and a third metallic drain electrode 41, which are connected to the upper surface of the barrier layer 15, a PFET gate dielectric layer 43 is arranged on an upper surface of the third P-type gallium nitride cap layer 42, and a third metallic gate electrode 44 is arranged on an upper surface of the PFET gate dielectric layer 43.

The first metallic source electrode 21 and the third metallic gate electrode 44 are connected via a first metallic interconnector V1 and connected to an input gate voltage, the first metallic drain electrode 24, the second metallic gate electrode 33 and the third metallic drain electrode 41 are connected via a second metallic interconnector V2, potentials of the second metallic source electrode 31 and the third metallic source electrode 45 are grounded, and the first metallic gate electrode 23 is connected to a 5 V potential.

The working principle of the device according to the present invention is shown in FIG. 5, in which when the first metallic gate electrode 23 is connected to a 5 V potential, a channel in the voltage-limiting tube region 20 is completely opened, the whole device starts working with the increase of the voltage of the first metallic source electrode 21 (i.e., the input gate voltage), the voltage of the second metallic gate electrode 33 increases with the increase of the input gate voltage, and then, due to the saturation characteristics of the gallium nitride HEMT device, the second metallic gate electrode 33 has the voltage clamped within its working voltage range and the gate current limited by the saturation current of the voltage-limiting tube region; and when the whole device is turned off, the input gate voltage decreases to the positive threshold voltage of the depletion-mode gallium nitride PFET, the channel in the bleed-off tube region 40 is completely opened, and charges stored in the second P-type gallium nitride cap layer 32 are bled off quickly.

### Embodiment 2

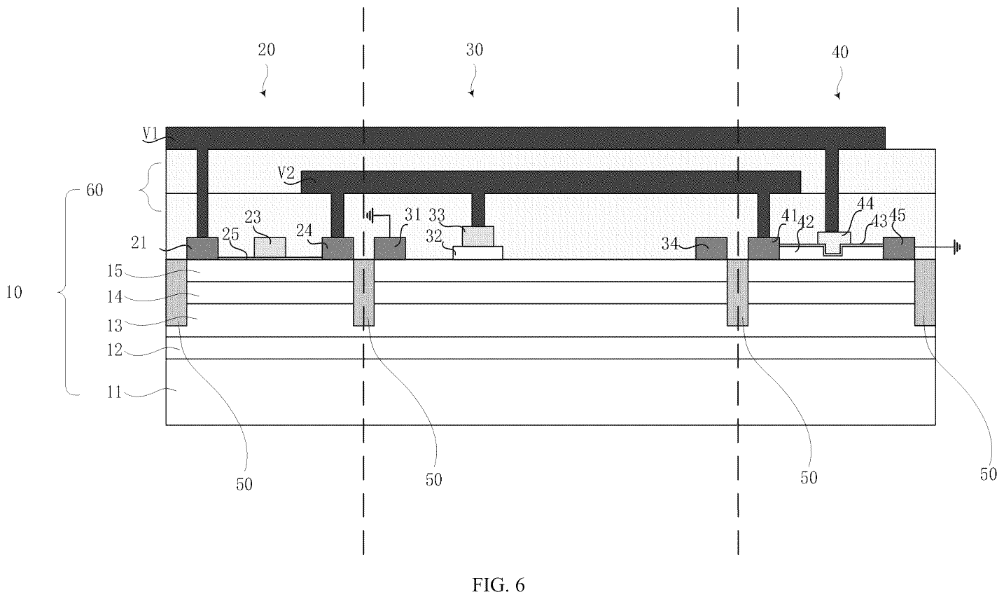

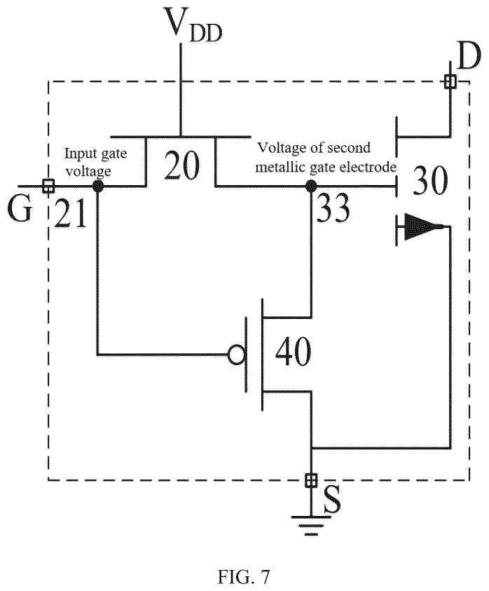

Based on the structure in Embodiment 1, this embodiment is characterized in that the voltage-limiting tube region may be provided with a depletion-mode gallium nitride HEMT device. Referring to FIG. 6, the voltage-limiting tube region 20 includes the first metallic source electrode 21, a depletion-mode gallium nitride gate dielectric layer 25 and the first metallic drain electrode 24, which are connected to the upper surface of the barrier layer 15, and the first metallic gate electrode 23 is arranged on an upper surface of the depletion-mode gallium nitride gate dielectric layer 25.

Like Embodiment 1, the first metallic source electrode 21 and the third metallic gate electrode 44 are connected via a first metallic interconnector V1 and connected to an input gate voltage, the first metallic drain electrode 24, the second metallic gate electrode 33 and the third metallic drain electrode 41 are connected via a second metallic interconnector V2, and potentials of the second metallic source electrode 31 and the third metallic source electrode 45 are grounded.

Unlike Embodiment 1, in this embodiment, the potential of the first metallic gate electrode 23 is grounded.

In the present invention, the voltage-limiting tube region improves the gate voltage range of the device; the first metallic gate electrode is set to a constant potential that is always greater than its threshold voltage to ensure the complete opening of the channel of the voltage-limiting tube region; the leakage current on the second metallic gate electrode in the power tube region first increases with the increase of the input gate voltage and then remains unchanged under the limitation by the saturation current from the voltage-limiting tube region; the voltage of the second metallic gate electrode in the power tube region is stabilized within its working voltage range; and the increased part of the input gate voltage is applied between the source and drain in the voltage-limiting tube region, such that the gate voltage swing of the device is improved.

Described above provides only the preferred embodiments of the present invention, and is not intended to impose any limitation to the scope of the present invention. Any changes and modifications made by those of ordinary skill in the art of the present invention based on the above disclosure should fall within the protection scope of the claims.

What is claimed is:

1. A gallium nitride power device with a wide-range working gate voltage, comprising: a base, the base comprising a substrate, on which a nucleating layer, a buffer layer, a channel layer, a barrier layer and a passivation layer are arranged in sequence; and isolation regions, wherein a voltage-limiting tube region, a power tube region and a bleed-off tube region are arranged on the barrier layer;
the voltage-limiting tube region comprises a first metallic source electrode, a first P-type gallium nitride cap layer and a first metallic drain electrode, which are connected to an upper surface of the barrier layer, and a first metallic gate electrode is arranged on an upper surface of the first P-type gallium nitride cap layer;
the power tube region comprises a second metallic source electrode, a second P-type gallium nitride cap layer and a second metallic drain electrode, which are connected to the upper surface of the barrier layer, and a second metallic gate electrode is arranged on an upper surface of the second P-type gallium nitride cap layer;
the bleed-off tube region comprises a third metallic source electrode, a third P-type gallium nitride cap layer and a third metallic drain electrode, which are connected to the upper surface of the barrier layer, a PFET gate dielectric layer is arranged on an upper surface of the third P-type gallium nitride cap layer, and a third metallic gate electrode is arranged on an upper surface of the PFET gate dielectric layer.

2. The gallium nitride power device with the wide-range working gate voltage according to claim 1, wherein the bleed-off tube region has characteristics of a depletion-mode gallium nitride PFET device as follows: when a voltage of the third metallic gate electrode is less than a positive threshold voltage, the device is turned on; and when the voltage of the third metallic gate electrode is greater than the positive threshold voltage, the device is turned off.

3. The gallium nitride power device with the wide-range working gate voltage according to claim 1, wherein the third P-type gallium nitride cap layer has a thickness of 50 nm to 300 nm.

4. The gallium nitride power device with the wide-range working gate voltage according to claim 1, wherein the third P-type gallium nitride cap layer is shaped as a groove.

5. The gallium nitride power device with the wide-range working gate voltage according to claim 1, wherein a groove of the third P-type gallium nitride cap layer has a maximum depth of 270 nm.

6. The gallium nitride power device with the wide-range working gate voltage according to claim 1, wherein the PFET gate dielectric layer has a depth of 1 nm to 50 nm.

7. The gallium nitride power device with the wide-range working gate voltage according to claim 1, wherein the PFET gate dielectric layer is one or a combination of several of silicon nitride, aluminum nitride, alumina and silicon oxide.

8. The gallium nitride power device with the wide-range working gate voltage according to claim 1, wherein the first metallic source electrode and the third metallic gate electrode are connected via a first metallic interconnector and connected to an input gate voltage, the first metallic drain electrode, the second metallic gate electrode and the third metallic drain electrode are connected via a second metallic interconnector, and potentials of the second metallic source electrode and the third metallic source electrode are grounded.

9. The gallium nitride power device with the wide-range working gate voltage according to claim 1, wherein the voltage-limiting tube region alternatively comprises the first metallic source electrode, a depletion-mode gallium nitride gate dielectric layer and the first metallic drain electrode, which are connected to the upper surface of the barrier layer, and the first metallic gate electrode is arranged on an upper surface of the depletion-mode gallium nitride gate dielectric layer.

10. The gallium nitride power device with the wide-range working gate voltage according to claim 2, wherein the third P-type gallium nitride cap layer has a thickness of 50 nm to 300 nm.

11. The gallium nitride power device with the wide-range working gate voltage according to claim 2, wherein the third P-type gallium nitride cap layer is shaped as a groove.

12. The gallium nitride power device with the wide-range working gate voltage according to claim 2, wherein a groove of the third P-type gallium nitride cap layer has a maximum depth of 270 nm.

13. The gallium nitride power device with the wide-range working gate voltage according to claim 6, wherein the PFET gate dielectric layer is one or a combination of several of silicon nitride, aluminum nitride, alumina and silicon oxide.
